(19) United States
(12) Patent Application Publication
(10) Pub. No.: US 2024/0379661 A1
(43) Pub. Date: Nov. 14, 2024

(54) SEMICONDUCTOR DEVICE

(71) Applicant: Mitsubishi Electric Corporation, Tokyo (JP)

(72) Inventors: Masaki SUDO, Tokyo (JP); Tomohito KUDO, Tokyo (JP)

(73) Assignee: Mitsubishi Electric Corporation, Tokyo (JP)

(21) Appl. No.: 18/688,228

(22) PCT Filed: Sep. 8, 2021
(86) PCT No.: PCT/JP2021/032950

§ 371 Date: Feb. 29, 2024

(51) Int. Cl. H01L 27/06; H01L 29/06; H01L 29/739; H01L 29/861

(52) U.S. Cl. CPC H01L 27/0664; H01L 29/0696; H01L 29/7397; H01L 29/8613

(57) ABSTRACT

An object is to provide a technique that can improve the accuracy of detecting the current in the main IGBT region using the current in the sense IGBT region. The semiconductor device includes a first IGBT region, a diode region, and a second IGBT region. The first IGBT region and the second IGBT region include a single collector layer having a first conductivity type, the diode region includes a cathode layer adjacent to the collector layer in the first IGBT region and having a second conductivity type, and the second IGBT region further includes an impurity layer adjacent to the collector layer in the second IGBT region and having the second conductivity type.

### TECHNICAL FIELD

The present disclosure relates to a semiconductor device.

### BACKGROUND ART

In order to protect a semiconductor element included in a semiconductor device, a technique has been proposed in which a sensing semiconductor element is provided to detect a current flowing through the semiconductor element. For example, Patent Document 1 proposes a configuration in which a peripheral region surrounding the collector layer in a sense Insulated Gate Bipolar Transistor (IGBT) region in a plan view is provided in order to suppress characteristic fluctuations of the sense IGBT, which is a sensing semiconductor element.

### PRIOR ART DOCUMENTS

### Patent Document(s)

[Patent Document 1] Japanese Patent Application Laid-Open No. 2019-21885

### SUMMARY

### Problem to be Solved by the Invention

The peripheral region of Patent Document 1 is designed to surround the sense IGBT region in plan view, and the hall injection reduction rate in the sense IGBT region caused by the peripheral region acts in such a manner that it becomes greater than the hall injection reduction rate in the main IGBT caused by the cathode layer in the main diode region. As a result, the difference between the current density in the sense IGBT region and the current density in the main IGBT region becomes relatively large, resulting in a problem that the accuracy of detecting the current in the main IGBT region using the current in the sense IGBT region decreases.

Therefore, the present disclosure has been made in view of the above-mentioned problems, and an object thereof is to provide a technique that can improve the accuracy of detecting the current in the main IGBT region using the current in the sense IGBT region.

### Means to Solve the Problem

According to the present disclosure, a semiconductor device includes a semiconductor substrate, a first IGBT region and a diode region provided adjacent to each other on the semiconductor substrate, and a second IGBT region provided on the semiconductor substrate spaced apart from the first IGBT region and the diode region, and for detecting a current flowing through the first IGBT region, in which the first IGBT region and the second IGBT region include a single collector layer having a first conductivity type, the diode region includes a cathode layer adjacent to the collector layer in the first IGBT region and having a second conductivity type, and the second IGBT region further includes an impurity layer adjacent to the collector layer in the second IGBT region and having the second conductivity type.

### Effects of the Invention

According to the present disclosure, the diode region includes a cathode layer adjacent to the collector layer in the first IGBT region and having a second conductivity type, and the second IGBT region includes an impurity layer adjacent to the collector layer in the second IGBT region and having the second conductivity type. According to such a configuration, the accuracy of detecting the current in the main IGBT region using the current in the sense IGBT region can be improved.

The purpose, feature, phase, and advantage of the present disclosure will become more apparent from the following description and the accompanying drawings.

### BRIEF DESCRIPTION OF DRAWINGS

FIG. 1 A plan view illustrating a configuration of a back surface side of a semiconductor device according to Embodiment 1.

FIG. 2 A cross-sectional view illustrating a configuration of the semiconductor device according to Embodiment 1.

FIG. 3 A cross-sectional view illustrating a configuration of a semiconductor device according to Modification of Embodiment 1.

### DESCRIPTION OF EMBODIMENT(S)

Embodiment will be described below with reference to the accompanying drawings. The features described in each Embodiment below are illustrative, and all features are not necessarily essential. Also, in the description given below, the same or similar reference numerals are given to the same components in a plurality of Embodiments, and different components will be mainly explained. Also, in the following description, terms indicating specific positions or directions such as “upper”, “lower”, “left”, “right”, “front”, and “back” may not necessarily coincide with the positions or directions at the time of implementation. Also, when mentioning a certain part having a higher concentration than another part is, for example, about the average concentration of a certain part being higher than the average concentration of another part. Conversely when mentioning a certain part having a lower concentration than another part is, for example, about the average concentration of a certain part being lower than the average concentration of another part. Although in the following description, the first conductive type represents p-type and the second conductive type represents n-type, the first conductive type may present p-type and the second conductive type may represent n-type.

### Embodiment 1

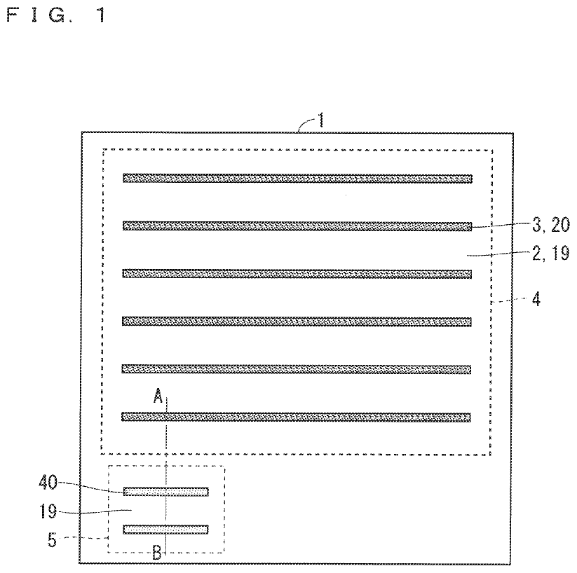

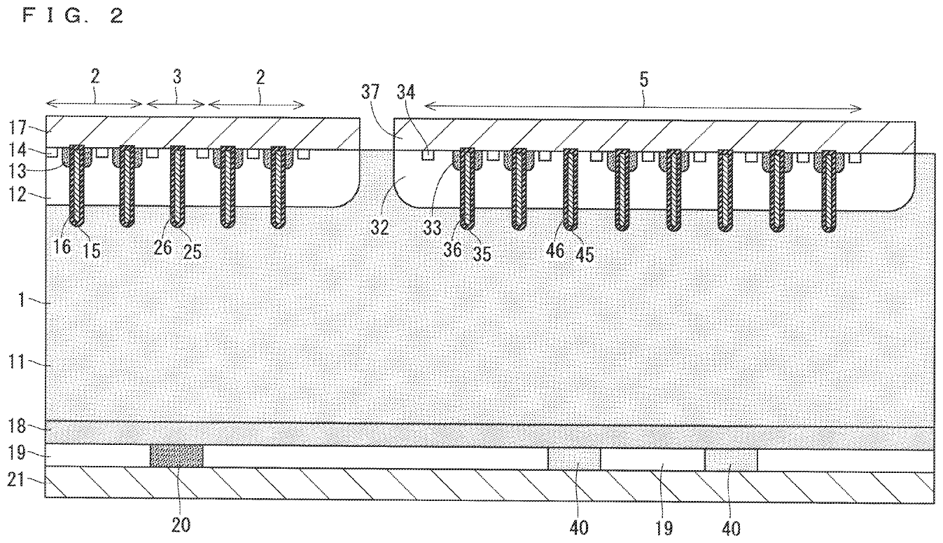

FIG. 1 is a plan view illustrating a configuration of a back surface side of a semiconductor device according to Embodiment 1 and FIG. 2 is a cross-sectional view illustrating a configuration taken along the line A-B of FIG. 1.

The semiconductor device according to Embodiment 1 includes a semiconductor substrate 1, a main IGBT region 2 being a first IGBT region, a main diode region 3 being a diode region, and a sense IGBT region 5 being a second IGBT region. Note that the main IGBT region 2 and the main diode region 3 are included in a main region 4.

The main IGBT region 2 and main diode region 3 are provided adjacent to each other on the semiconductor substrate 1. The sense IGBT region 5 is provided on the semiconductor substrate 1, spaced apart from the main region 4, which includes the main IGBT region 2 and the main diode region 3. As described above, in Embodiment 1, the semiconductor substrate 1 includes the main IGBT region 2, the main diode region 3, and the sense IGBT region 5 in a monolithic manner.

The semiconductor substrate 1 may be composed of a conventional semiconductor wafer or an epitaxial growth layer. The material of the semiconductor substrate 1 includes, for example, silicon (Si) or a wide bandgap semiconductor. A wide bandgap semiconductor includes, for example, silicon carbide (SIC), gallium nitride (GaN), diamond, or the like. When the material of the semiconductor substrate 1 includes a wide bandgap semiconductor, this enables stable operation at high temperatures and high voltages and increased switching speed.

The semiconductor substrate 1, which has been subjected to various manufacturing steps, includes an n′-type drift layer 11, p-type base layers 12, 32, n⁺-type source layers 13, 33, p⁺-type diffusion layers 14, 34, an n-type buffer layer 18, a p-type collector layer 19, an n-type cathode layer 20, and an n-type impurity layer 40. Note that in Embodiment 1, it is assumed that the impurity concentration of the drift layer 11 is the same as the impurity concentration of the semiconductor substrate 1 before going through various manufacturing steps, however, the impurity concentration is not limited thereto.

The base layers 12, 32 are selectively disposed in the upper portion of the drift layer 11, the source layer 13 and the diffusion layer 14 are selectively disposed in the upper portion of the base layer 12, and the source layer 33 and the diffusion layer 34 are selectively disposed in the upper portion of the base layer 32. The buffer layer 18 is disposed under the drift layer 11, and the collector layer 19, the cathode layer 20, and the impurity layer 40 are selectively disposed under the drift layer 11.

Next, common components common to some of the main IGBT region 2, the main diode region 3, and the sense IGBT region 5 will be explained. The main IGBT region 2, the main diode region 3, and the sense IGBT region 5 include the single drift layer 11, the single buffer layer 18, and a single back surface electrode 21. The main IGBT region 2 and the main diode region 3 include the single base layer 12 and a single front surface electrode 17 corresponding to the main region 4. As illustrated in FIGS. 1 and 2, the main IGBT region 2 and the sense IGBT region 5 include the single collector layer 19. Next, the main IGBT region 2, the main diode region 3, and the sense IGBT region 5 will be described individually.

### <Main IGBT Region>

The main IGBT region 2 includes the drift layer 11, the base layer 12, the source layer 13, the diffusion layer 14, an insulating film 15, a gate electrode 16, the front surface electrode 17, the buffer layer 18, the collector layer 19, and the back surface electrode 21.

A first trench is provided from the upper surface of the source layer 13, extending through the source layer 13 and the base layer 12, and reaching the drift layer 11. The insulating film 15 is provided on the inner wall of the first trench, and the gate electrode 16 is provided on the first trench with the insulating film 15 interposed therebetween.

The front surface electrode 17 is provided on the surfaces of the base layer 12, the source layer 13, and the diffusion layer 14 (that is, the front surface of the semiconductor substrate 1). The back surface electrode 21 is provided on the surface of the collector layer 19 (that is, the back surface of the semiconductor substrate 1).

The main IGBT region 2 configured as described above includes a region that functions as a main IGBT. Note that the main IGBT region 2 corresponds to the region of the main region 4 where the collector layer 19 is provided.

### <Main Diode Region>

The main diode region 3 includes the drift layer 11, the base layer 12, the diffusion layer 14, an insulating film 25, a conductive portion 26, the front surface electrode 17, the buffer layer 18, the cathode layer 20, and the back surface electrode 21.

A second trench is provided from the upper surface of the base layer 12, extending through the base layer 12 and reaching the drift layer 11. The insulating film 25 is provided on the inner wall of the second trench, and the conductive portion 26 is provided on the second trench with the insulating film 25 interposed therebetween. The cathode layer 20 is adjacent to the collector layer 19 of main IGBT region 2.

The front surface electrode 17 is provided on the surfaces of the base layer 12 and the diffusion layer 14 (that is, the front surface of the semiconductor substrate 1). The back surface electrode 21 is provided on the surface of the cathode layer 20 (that is, the back surface of the semiconductor substrate 1).

The main diode region 3 configured as described above includes a region that functions as a main diode. Note that the main diode region 3 corresponds to the region of the main region 4 where the cathode layer 20 is provided.

### <Sense IGBT Region>

The sense IGBT region 5 includes the drift layer 11, the base layer 32, the source layer 33, the diffusion layer 34, insulating films 35, 45, a gate electrode 36, a conductive portion 46, a front surface electrode 37, the buffer layer 18, the collector layer 19, the impurity layer 40, and the back surface electrode 21.

A third trench is provided from the upper surface of the source layer 33, extending through the source layer 33 and the base layer 32, and reaching the drift layer 11. The insulating film 35 is provided on the inner wall of the third trench, and the gate electrode 36 is provided on the third trench with the insulating film 35 interposed therebetween.

A fourth trench is provided from the upper surface of the base layer 32, extending through the base layer 32 and reaching the drift layer 11. The insulating film 45 is provided on the inner wall of the fourth trench, and the conductive portion 46 is provided on the fourth trench with the insulating film 45 interposed therebetween. The impurity layer 40 is provided below the conductive portion 46 and adjacent to the collector layer 19 of the sense IGBT region 5. In Embodiment 1, the impurity layer 40 is formed without ion implantation, and the impurity concentration of the impurity layer 40 is the same or substantially the same as that of drift layer 11.

The front surface electrode 37 is provided on the surfaces of the base layer 32, the source layer 33, and the diffusion layer 34 (that is, the front surface of the semiconductor substrate 1). The back surface electrode 21 is provided on the surface of the collector layer 19 and the impurity layer 40 (that is, the back surface of the semiconductor substrate 1).

The sense IGBT region 5 configured as above is a region for detecting the current flowing through the main IGBT region 2, and includes a region that functions as a sense IGBT for detecting the current flowing through the main IGBT region 2. The area of the sense IGBT region 5 is, for example, approximately one thousandth of the area of the main IGBT region 2.

### Summary of Embodiment 1

According to the semiconductor device configured as described above, the sense IGBT region 5 includes the impurity layer 40, this allows the hole injection reduction rate of the sense IGBT region 5 to be brought close to the hole injection reduction rate of the main IGBT region 2. This reduces the difference between the current density in the collector layer 19 of the sense IGBT region 5 and the current density in the main IGBT region 2, thereby bringing the ratio of the current in the collector layer 19 of the sense IGBT region 5 to the current in the main IGBT region 2 close to their area ratio. Consequently, the accuracy of detecting the current in the main IGBT region 2 using the current in the collector layer 19 of the sense IGBT region 5 can be improved.

### Modification 1

In Embodiment 1, the area ratio of the impurity layer 40 to the collector layer 19 of the sense IGBT region 5 in plan view may correspond to the area ratio of the cathode layer 20 to the collector layer 19 of the main IGBT region 2 in plan view. In other words, the area ratio of the impurity layer 40 to the collector layer 19 of the sense IGBT region 5 in plan view may be the same or substantially the same as the area ratio of the cathode layer 20 to the collector layer 19 of the main IGBT region 2 in plan view. Here, the two area ratios being substantially the same means that one area ratio of the two area ratios falls within +10% of the other area ratio, and depending on the configuration, it falls within +5%. According to such a configuration, the ratio of the current in the collector layer 19 of the sense IGBT region 5 to the current in the main IGBT region 2 can be brought closer to their area ratio. Consequently, the accuracy of detecting the current in the main IGBT region 2 using the current in the collector layer 19 of the sense IGBT region 5 can be improved.

### Modification 2

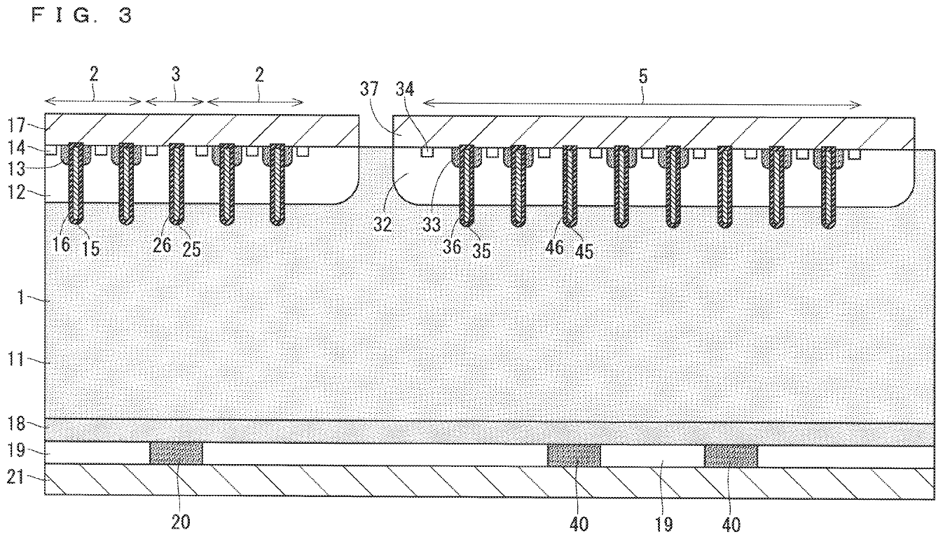

In Embodiment 1, as illustrated in FIG. 1, the impurity concentration of the impurity layer 40 is the same or substantially the same as the impurity concentration of the drift layer 11, and is different from the impurity concentration of the cathode layer 20, however, this is not limited to this. For example, as illustrated in FIG. 3, the n-type impurity concentration of the impurity layer 40 may correspond to the n-type impurity concentration of the cathode layer 20. That is, the n-type impurity concentration of the impurity layer 40 may be the same or substantially the same as the n-type impurity concentration of the cathode layer 20. Here, the two impurity concentrations being substantially the same means that one impurity concentration of the two impurity concentrations falls within ±10% of the other impurity concentration, and depending on the configuration, it falls within ±5%.

According to such a configuration, during the freewheeling operation of the main diode region 3, the ratio of the current in the impurity layer 40 of the sense IGBT region 5 to the current in the main diode region 3 can be brought close to their area ratio. Consequently, the accuracy of detecting the current in the main diode region 3 during freewheeling operation using the current in the impurity layer 40 of the sense IGBT region 5 can be improved.

Also, the ratio of the current in the collector layer 19 of the sense IGBT region 5 to the current in the main IGBT region 2 can be brought closer to their area ratio. Consequently, the accuracy of detecting the current in the main IGBT region 2 using the current in the collector layer 19 of the sense IGBT region 5 can be improved.

It should be noted that Embodiment can be appropriately modified or omitted.

The forgoing description is in all aspects illustrative and not restrictive. It is therefore understood that numerous undescribed Modifications can be devised.

### EXPLANATION OF REFERENCE SIGNS

1 semiconductor substrate, 2 main IGBT region, 3 main diode region, 5 sense IGBT region, 19 collector layer, 20 cathode layer, 40 impurity layer.

1. A semiconductor device comprising:
a semiconductor substrate;
a first IGBT region and a diode region provided adjacent to each other on the semiconductor substrate; and
a second IGBT region provided on the semiconductor substrate spaced apart from the first IGBT region and the diode region, and for detecting a current flowing through the first IGBT region, wherein
the first IGBT region and the second IGBT region include a single collector layer having a first conductivity type,
the diode region includes a cathode layer adjacent to the collector layer in the first IGBT region and having a second conductivity type, and
the second IGBT region further includes an impurity layer adjacent to the collector layer in the second IGBT region and having the second conductivity type.

2. The semiconductor device according to claim 1, wherein
an area ratio of the impurity layer to the collector layer in the second IGBT region in plan view corresponds to an area ratio of the cathode layer to the collector layer in the first IGBT region in plan view.

3. The semiconductor device according to claim 1, wherein
a second conductivity type impurity concentration of the impurity layer corresponds to a second conductivity type impurity concentration of the cathode layer.

4. The semiconductor device according to claim 2, wherein
a second conductivity type impurity concentration of the impurity layer corresponds to a second conductivity type impurity concentration of the cathode layer.
